(19) United States
(12) Patent Application Publication
(10) Pub. No.: US 2012/0094450 A1
(43) Pub. Date: Apr. 19, 2012

(54) MANUFACTURING METHOD OF MULTI-LEVEL CELL NOR FLASH MEMORY

(75) Inventors: Yider Wu, Chu-Pei City (TW); Sheng-Da Liu, Chu-Pei City (TW)

(73) Assignee: EON SILICON SOLUTION INC., CHU-PEI CITY (TW)

(21) Appl. No.: 12/907,077

(22) Filed: Oct. 19, 2010

(51) Int. Cl. H01L 21/336

(52) U.S. Cl. 438/257; 257/E21.409

(57) ABSTRACT

A manufacturing method of a multi-level cell NOR flash memory includes the steps of forming a memory cell area and a peripheral circuit area with the same depth of a shallow trench isolation structure, and the depth ranges from 2400 Å to 2700 Å; forming a non-self-aligned gate structure; performing a self-alignment source manufacturing process; and forming a common source area and a plurality of drain areas. The manufacturing method achieves a high integration density between components and provides a better thermal budget and a better dosage control to the multi-level cell NOR flash memory to improve the production yield rate.

### FIELD OF THE TECHNOLOGY

The present invention relates to a manufacturing method of a flash memory, in particular to a manufacturing method of a multi-level cell NOR flash memory.

### BACKGROUND

As the functions of electronic products such as mobile phones, music players (MP3 players), video players, digital cameras and electronic books advance, the volume of system data becomes increasingly larger. Therefore, a stable and fast access speed is required, and flash memory manufacturers constantly improve the density and access speed of a memory chip, and thus the flash memory is shifted from single level cell (SLC) to multi level cell (MLC) gradually. With the MLC technology, the production cost is lower than the SLC, and the MLC technology further achieves a multi-level high-density flash memory and provides a larger storage capacity.

The NOR flash memory has the high-speed write-in and erase capabilities as well as a complete address and a data interface, and the memory can be accessed randomly, and thus the NOR flash memory is suitable for applications for devices such as BIOS and firmware that do not need frequent updates, and the NOR flash memory has a life of 10,000 to 1,000,000 erase cycles. Besides the motherboard of personal computer stores BIOS data in the NOR flash memory, present NOR flash memories are also used for storing system data of mobile phones and handheld electronic devices. With the high reading speed, the NOR flash memory can satisfy the booting requirements of the handheld devices.

### SUMMARY

To achieve the foregoing and other objectives, it is a primary objective of the present invention to provide a manufacturing method that achieves a better integration density of components.

Another objective of the present invention is to provide a manufacturing method of a multi-level cell NOR flash memory having a better thermal budget and a better dosage control.

To achieve the foregoing and other objectives, the manufacturing method of a multi-level cell NOR flash memory in accordance with the present invention comprises the steps of: forming a plurality of first shallow trench isolation structures and a plurality of second shallow trench isolation structures on a substrate, and the first shallow trench isolation structures are disposed in a memory cell area, and the second shallow trench isolation structures are disposed in a peripheral circuit area, and the depth of the first shallow trench isolation structures is equal to the depth of the second shallow trench isolation structures, where the depth of first and second shallow trench isolation structures ranges from 2400 Å to 2700 Å; forming a plurality of gate stack structures in the memory cell area, wherein the running direction of the gate stack structure is perpendicular to the first shallow trench isolation structures; performing a self-alignment source manufacturing process, to remove the first shallow trench isolation structures between each pair of adjacent gate stack structures; and forming a common source area in the substrate between a pair of adjacent gate stack structures, and forming a plurality of drain areas in the substrate on another side of each gate stack structure, wherein the drain areas are isolated from the first shallow trench isolation structures.

In a preferred embodiment, the step of forming the drain areas includes two times of implantation process, an arsenic ion implant process and a phosphorous ion implant process, wherein the dosage of the arsenic ion implantation is 2×1015˜4×1015(atom/cm²), and the power is 40˜50 (Kev), and the dosage of phosphorous ion implantation is 2×1014˜2×1015(atom/cm2), and the power is 20˜30 (Kev).

With the manufacturing method of the present invention, the memory cell area and the peripheral circuit area of the shallow trench isolation structure have the same depth for achieving a high integration density among components easily, and a non-self-aligned gate structure further provides a better thermal budget and a better dosage control to the multi-level cell NOR flash memory. In addition the implantation conditions of the drain area further reduce the defects derived by a metallization process and improve the production yield rate of the memory devices.

### BRIEF DESCRIPTION OF THE DRAWINGS

FIGS. 1 to 5 are schematic perspective views of a multi-level cell NOR flash memory at different manufacturing steps in accordance with a preferred embodiment of the present invention respectively; and

FIG. 6 is a flow chart of a manufacturing method of a multi-level cell NOR flash memory in accordance with a preferred embodiment of the present invention.

### DETAILED DESCRIPTION

The objects, characteristics and effects of the present invention will become apparent with the detailed description of the preferred embodiments and the illustration of related drawings as follows.

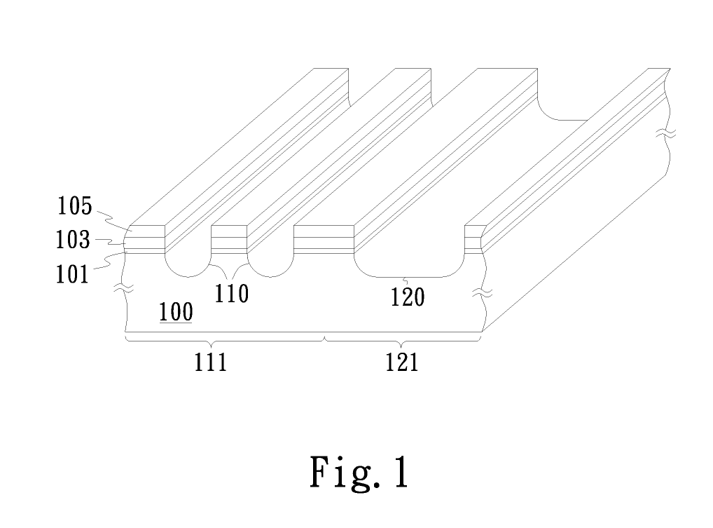

With reference to FIG. 1 for a schematic perspective view of a multi-level cell NOR flash memory at a different manufacturing step in accordance with a preferred embodiment of the present invention, a substrate 100 is provided, and a pad oxide layer 101 and a mask layer 103 are formed sequentially on the substrate 100, wherein the mask layer 103 is made of silicon oxide. A lithographic etching process is performed, and a photoresist layer 105 having a trench pattern is formed on the mask layer 103, and the photoresist layer 105 is used as a mask, and the exposed mask layer 103, the pad oxide layer 101 and a portion of the substrate 100 are etched to form a plurality of first shallow trenches 110 and a plurality of second shallow trenches 120, wherein FIG. 1 only shows a portion of the trench structure. The first and second shallow trenches 110, 120 have a depth ranging from 2400 Å to 2700 Å, and the second shallow trenches have a width greater than the first shallow trenches 110. The first shallow trenches 110 are disposed in the memory cell area 111, and an area other than the memory cell area 111 falls in a peripheral circuit area 121.

The substrate 100 is made of silicon (Si), silicon-germanium (SiGe), silicon on insulator (SOI), silicon germanium on insulator (SGOI), or germanium on insulator (GOI). In this preferred embodiment, the substrate 100 is made of silicon and doped with boron, such that the substrate 100 becomes a p-type semiconductor substrate.

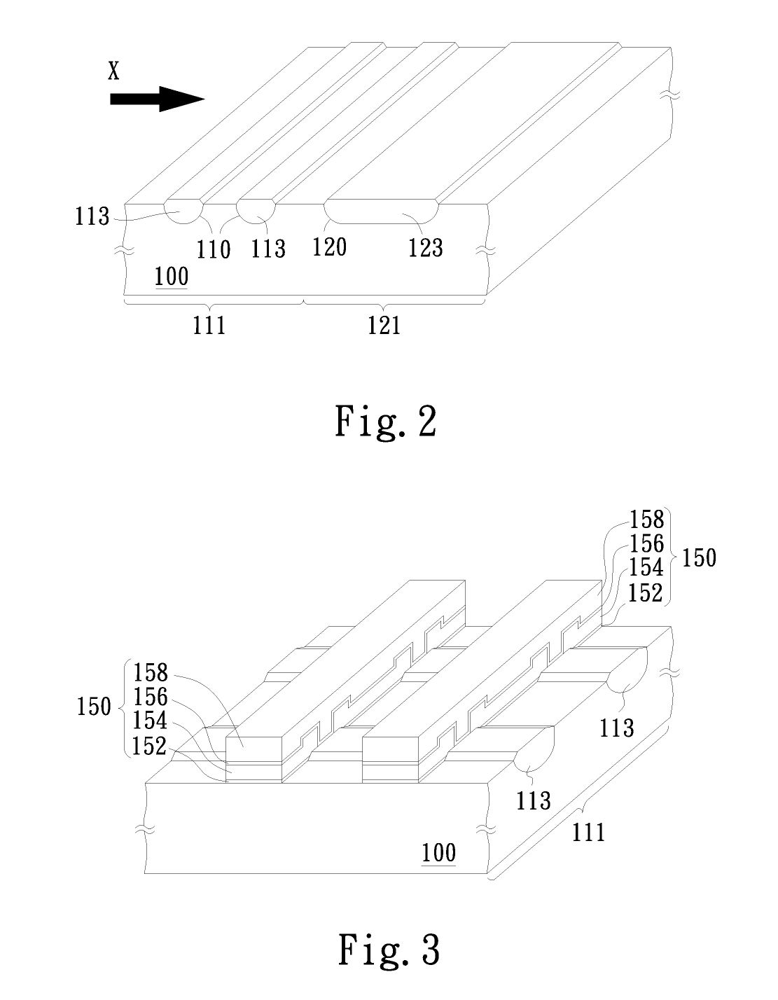

With reference to FIG. 2, an insulating material is filled into the first shallow trenches 110 and the second shallow trenches 120 to form a first shallow trench isolation structure 113 and a second shallow trench isolation structure 123 respectively. The method of filling the insulating material into the first shallow trenches 110 and the second shallow trenches 110 is described as follows. The insulating material is covered onto the substrate 100 completely and filled up in the first shallow trench 110 and second shallow trench 120, and a chemical mechanical polishing (CMP) process is used for removing the insulating material outside the first shallow trench 110 and the second shallow trench 120. In addition, the insulating material is silicon oxide produced by the chemical vapor deposition (CVD). If the insulating material is silicon oxide, then an annealing process can be added after the aforementioned insulating material is filled, and the insulating material is densified. The mask layer 103 and the pad oxide layer 101 are removed sequentially to expose a surface of the substrate 100.

With reference to FIG. 3, the viewing direction of the perspective view is the Arrow X direction as shown in FIG. 2. A plurality of gate stack structures 150 are formed on the substrate 100 of the memory cell area 111. Each gate stack structure 150 is comprised of a tunnel oxide layer 152, a floating gate 154, a dielectric layer 156 and a control gate 158 stacked bottom up, wherein the tunnel oxide layer 152 and floating gate 154 of a same gate stack structure 150 are arranged in a row, and the tunnel oxide layer 152 is disposed on the substrate 100 between the first shallow trench isolation structures 113, and each floating gate 154 is disposed on a tunnel oxide layer 152. The floating gates 154 are made of a polysilicon material. In addition, the dielectric layer 156 is covered onto the floating gate 154, and the dielectric layer 156 can be a silicon oxide/silicon nitride/silicon oxide (ONO) composite; and the control gate 158 is disposed on the dielectric layer 156, wherein the direction of arranging the control gate 158 is perpendicular to the first shallow trench isolation structure 113, and the control gate 158 is made of a polysilicon material.

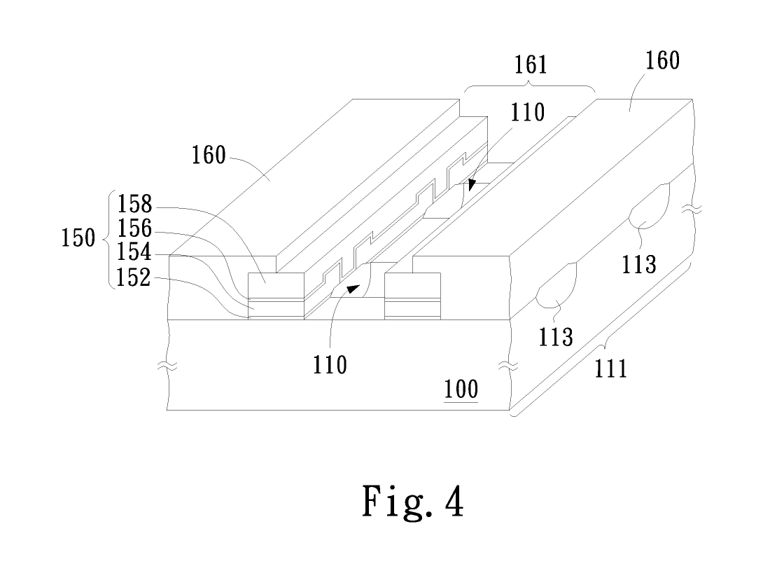

With reference to FIG. 4, a self-alignment source manufacturing process is performed, wherein a photoresist layer 160 with a pattern is formed on the substrate 100, and the photoresist layer 160 has an opening 161 for exposing the substrate 100 between the control gates 158 and the first shallow trench isolation structure 113, and the opening 161 has a width greater than the interval between control gates 158 to assure the first shallow trench isolation structure 113 between the control gates 158 can be exposed completely. The photoresist layer 160 is used as an etching mask, and the exposed first shallow trench isolation structure 113 is removed to expose the first shallow trench 110 disposed between the control gates 158.

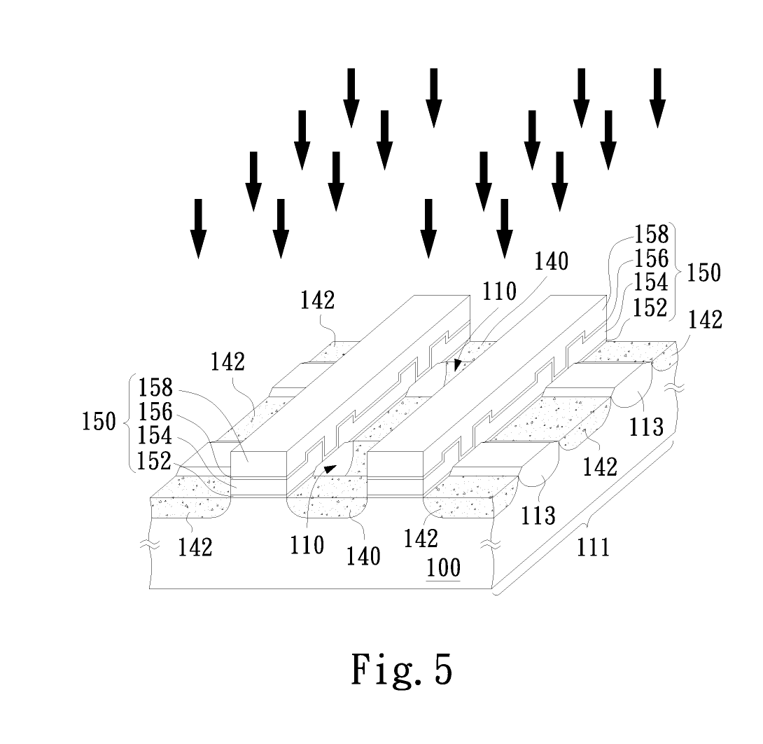

With reference to FIG. 5, the photoresist layer 160 is removed, and then the control gate 158 is used as a mask to perform the ion implant process to form a common source area 140 in the substrate 100 between the control gates 158 and a surface layer of the first shallow trenches 110, while a plurality of drain areas 142 are formed on a surface layer of the substrate 100 on another side of the control gate 158, and the drain areas 142 are separated from one another by the first shallow trench isolation structures 113.

In a preferred embodiment, the step of forming the drain areas 142 includes two times of ion implant processes as described below.

(1) An arsenic ion implant process has a dosage of 2×1015˜4×1015 (atom/cm²) and a power of 40˜50 (Kev).

(2) A phosphorous ion implant process has a dosage of 2×1014˜2×1015 (atom/cm²) and a power of 20˜30 (Kev).

The sequence of the aforementioned two times of ion implant processes is not limited to this arrangement only, but the sequence of the two processes can be switched.

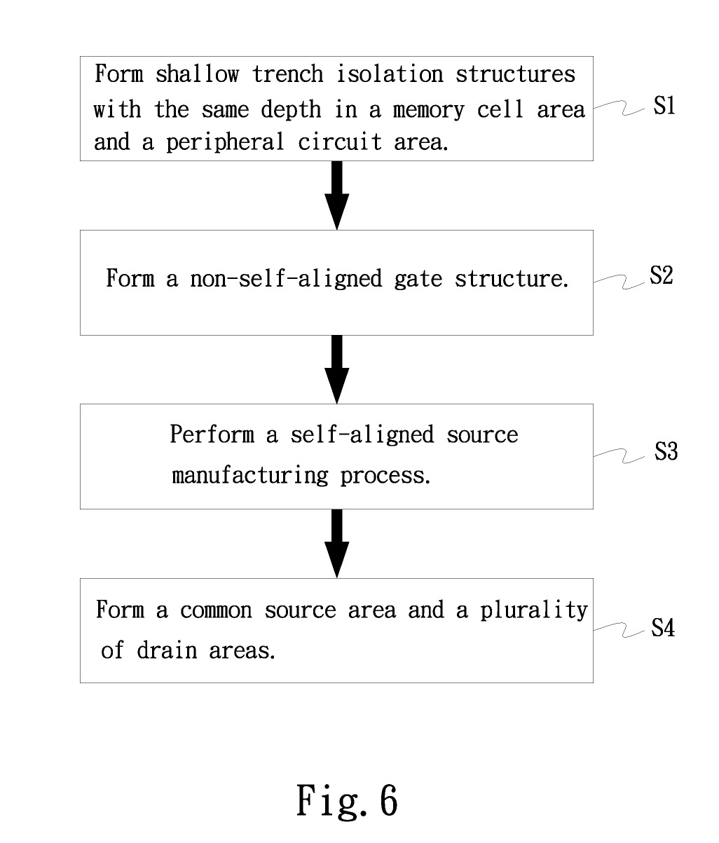

With reference to FIG. 6 for a flow chart of a manufacturing method in accordance with the present invention, the method comprises the steps of:

(S1) forming a plurality of first shallow trench isolation structures and a plurality of second shallow trench isolation structures on a substrate, wherein the first shallow trench isolation structures are disposed in a memory cell area, and the second shallow trench isolation structures are disposed in a peripheral circuit area, and the first shallow trench isolation structures have a depth equal to the depth of the second shallow trench isolation structures, and the first and second shallow trench isolation structures have a depth ranging from 2400 Å to 2700 Å;

(S2) performing a non-self-aligned gate stack structure manufacturing process to form a plurality of gate stack structures in the memory cell area, wherein the running direction of the gate stack structures is perpendicular to the first shallow trench isolation structures;

(S3) performing a self-alignment source manufacturing process to remove the first shallow trench isolation structures between every pair of adjacent gate stack structures; and

(S4) forming a common source area in the substrate between every pair of adjacent gate stack structures, and forming a plurality of drain areas in the substrate on another side of every gate stack structure, wherein the drain areas are separated by the first shallow trench isolation structures.

In summation of the description above, the manufacturing method of a multi-level cell NOR flash memory in accordance with the present invention achieves a high integration density between components easily, and a non-self-aligned gate structure provides a better thermal budget and a better dosage control to the multi-level cell NOR flash memory to improve the production yield rate.

While the invention has been described by means of specific embodiments, numerous modifications and variations could be made thereto by those skilled in the art without departing from the scope and spirit of the invention set forth in the claims.

What is claimed is:

1. A manufacturing method of a multi-level cell NOR flash memory, comprising the steps of:
forming a plurality of first shallow trench isolation structures and a plurality of second shallow trench isolation structures on a substrate, and the first shallow trench isolation structures being disposed in a memory cell area, and the second shallow trench isolation structures being disposed in a peripheral circuit area, and the first shallow trench isolation structures having a depth equal to the depth of the second shallow trench isolation structures, and the depth of the first and second shallow trench isolation structures ranging from 2400 Å to 2700 Å;
forming a plurality of gate stack structures in the memory cell area, and the gate stack structures having a running direction perpendicular to the first shallow trench isolation structures;
performing a self-alignment source manufacturing process to remove the first shallow trench isolation structures between every pair of adjacent gate stack structures; and
forming a common source area in the substrate between every pair of adjacent gate stack structures, and forming a plurality of drain areas in the substrate on another side of each gate stack structure, and the drain areas being separated by the first shallow trench isolation structures.

2. The manufacturing method of claim 1, wherein the step of forming the drain areas comprises two times of implantation process, a arsenic ion implant process, and a phosphorus ion implant process, and the arsenic ion implant process has a dosage of 2×1015˜4×1015 (atom/cm²), and a power of 40˜50 (Kev), and the phosphorous ion implant process has a dosage of 2×1014˜2×1015 (atom/cm²), and a power of 20˜30 (Kev).
